(19) United States
(12) Patent Application Publication
(10) Pub. No.: US 2007/0054492 A1
(43) Pub. Date: Mar. 8, 2007

(54) Photoreactive removal of ion implanted resist

(76) Inventors: David J. Elliott, Wayland, MA (US); Ronald P. Millman JR., Taunton, MA (US); Victoria M. Chaplick, Sherborn, MA (US); Murray Tardif, Dunstable, MA (US); Krista Aiello, Hudson, NH (US); Kenneth J. Harte, Carlisle, MA (US)

Correspondence Address: HARRITY SNYDER, LLP, 11350 Random Hills Road, SUITE 600, FAIRFAX, VA, 22030, US

(21) Appl. No.: 11/498,992

(22) Filed: Aug. 4, 2006

Related U.S. Application Data
(63) Continuation-in-part of application No. 10/998,465, filed on Nov. 29, 2004.
Application No. 10/998,465 is a division of application No. 10/870,646, filed on Jun. 17, 2004.
(60) Provisional application No. 60/705,168, filed on Aug. 4, 2005.
(60) Provisional application No. 60/705,166, filed on Aug. 4, 2005.

(51) Int. Cl. B44C 1/22; H01L 21/302

(52) U.S. Cl. 438/689; 216/63

(57) ABSTRACT

A method for removing ion implanted photoresist from a surface of a substrate is provided. The method may include introducing a gas to a reaction chamber containing the substrate; illuminating the ion implanted photoresist with radiation from a laser in the presence of the gas; and scanning the radiation across the surface in the presence of the gas to photoreactively remove the ion implanted photoresist from the surface.

### CROSS REFERENCE TO RELATED APPLICATIONS

This application is a continuation-in-part of U.S. patent application Ser. No. 10/998,465 filed on Nov. 29, 2004, which is a divisional application of U.S. patent application Ser. No. 10/870,646 filed on Jun. 17, 2004 the disclosures of which are hereby incorporated by reference herein in their entirety. This application also claims priority to U.S. Provisional Patent Application No. 60/705,168 filed Aug. 4, 2005 (attorney docket number: 0047-0001CIP1) and U.S. Provisional Patent Application No. 60/705,166 filed Aug. 4, 2005 (attorney docket number: 0047-0001CIP2) the contents of which are hereby incorporated by reference in their entirety.

### BACKGROUND OF THE INVENTION

Integrated circuit manufacturing may pattern resist (also called ‘photoresist’) onto silicon wafers as a mask to facilitate selective etching or ion implantation processes. The resist pattern is formed by photolithography and the resist is subsequently hardbaked to better withstand the physical and chemical environments used in etching and/or ion implantation. Following ion implantation or etching, the resist is removed from the wafer. Proper operation of a fabricated semiconductor may require that resist be removed without damaging the surface of the silicon wafer.

During ion implantation, especially at high doses of >5×10¹⁴ atoms/cm², the impingement of high-energy ions and heat compacts and highly densifies the resist surface. This creates what is commonly described by those skilled in the art as a ‘crust’, a very brittle, carbonized and crosslinked, thin layer on top of a much thicker layer of unreacted resist. The carbonized resist surface crust is very difficult to react and remove because it effectively forms a barrier that traps solvents residing in the thicker resist lying below the crust.

Also, in plasma etching, a crust or post etch polymer may be formed in the resist or substrate. This crust is not typically as thick as a typical crust formed from ion implantation; however, it can be selectively removed from the lower resist layer.

Plasma ashers are used to remove the carbonized crustfrom the wafer. During the conventional plasma ashing process, the solvents under the crust evaporate and eventually build up enough pressure to burst through the crust, causing many pieces of hot, sticky carbonized resist to fall back onto the wafer through a process referred to as “popping.” Very corrosive acids and solvents are needed to remove these re-deposited pieces of broken crust from the surface of the wafer. For example, these particles may have to be undercut to remove them from the wafer surface since the particles are so strongly adhered to the wafer surface.

Plasma ashing is further typically performed with oxygen, and this process leaves an ‘ash’ or residue of material behind that requires the use of a wet bench and many corrosive chemicals to remove. Some plasma ashing processes also add small amounts of halogenated gasses such as fluorine or CF₄ to the oxygen to remove the residue, but these gasses will attack silicon and its oxides on the wafer surface. In some new processes, gate oxides are so thin that the current processes may etch holes through them, which is undesirable. Additionally, the increase in charged particles in the plasma from the addition of halogens may create electrical device damage; as opposed to physical etch damage.

Wet benches are used to remove material left behind by the plasma ashing process. For example, plasma ashing may leave behind both organic material and metallic material (e.g., trace metals that remain in the wafer surface after plasma ashing). Wet benches are large complex systems that use corrosive chemicals, such as standard clean 1 (SC-1) and standard clean 2 (SC-2), to remove the organic and metallic material remaining after plasma ashing. For example, SC-1, a mixture of ammonium hydroxide and hydrogen peroxide, may be used to remove organic residues, but it is also corrosive to certain metal layers used in wafer manufacturing. SC-2 is a dilute solution of hydrochloric acid (HCl) and hydrofluoric acid (HF) that may be used to remove metallic contaminates from the wafer surface, but it also attacks oxides. Organic and metallic materials, if left on the wafer surface, will degrade or destroy the performance of a finished wafer. Wet benches use multiple steps to attempt to balance the removal of contaminants with the damage done while removing these contaminants so as to obtain a satisfactory wafer yield rate during the wafer manufacturing process. As a result, process yields are lower since all finished chips on a wafer will not pass final inspections (e.g., probe inspections).

Since wet bench chemicals are corrosive, multiple rinsing steps are required to remove these chemicals after wet bench processing is completed. Both the corrosive chemicals and rinsing solutions contain hazardous materials and require special handling for proper disposal. Disposal costs can be expensive and may be a significant addition to the manufacturing costs for a finished wafer.

Plasma ashers typically operate in the 150-350° C. temperature range for best ashing rates, and these temperatures will cause the popping problems. High temperatures also cause implanted ions in the substrate to migrate or diffuse through the wafer, changing the device electrical properties. Despite these drawbacks, ashers are typically run hot in order to maintain acceptable ash times, since several wet process steps are then needed to remove the residue left from ashing, and the process time of the wet cleans is added to the ashing time to determine wafer throughput of the full process of resist strip. Total throughput is calculated by the addition of plasma ashing time and wet bench cleaning time. A typical plasma ashing time is 1-2 minutes, and wet bench chemical cleaning and drying typically add another 8-10 minutes, for a total process time per wafer of 9-12 minutes. The time needed to remove ion implanted resist with the present invention is less than two minutes, to which is added about 1 to 2 minutes of robot and vacuum pump time. There is a need in the art for a resist removal process that can operate at very low temperatures and maintain good wafer throughput.

Finally, wet processing of any kind is simply not compatible with many of the new low k porous films needed for advanced IC manufacturing. For example, it is proving to be very difficult to extract all the moisture from porous low k films, and a dry process may become a requirement to achieve consistent results.

Even the use of megasonic power to attempt to penetrate high aspect ratio topography, such as 10:1 aspect ratio contacts, has proven difficult. Control of megasonic field uniformity is a major challenge, as is the control of high power radio frequency power in ashers. Megasonics have been applied to wet cleaning solutions to achieve higher penetration of surface topography.

Smaller device geometries, along with porous low k films offer higher device switching speeds, necessary for increasing the speed of computers. These materials are rapidly being evaluated and integrated into advanced IC chips. As IC dimensions get smaller, the technology limit of these prior art methods will be reached. Therefore, new non-damaging cleaning and resist removal methods will be needed to allow these devices to be made reliably and economically.

In summary, plasma ashing combined with wet cleaning are the primary methods in the art for the removal of ion implanted resist. It is well known in the art that plasmas create charges that damage the substrate, and the wet benches cause etching and roughening of the wafer surface. Frequently, the plasma asher and wet bench process is repeated multiple times to remove all resist residues, causing silicon loss and degrading IC device performance. Moreover, future technology nodes, such as the 45 nm and 32 nm nodes, do not allow the degree of substrate loss associated with these conventional resist removal methods, as each technology node is defined by the smallest geometry fabricated on that particular device.

In further summary, plasma ashers and wet benches have high operating cost due to the use of complex processing and monitoring equipment and considerable facility infrastructure and support costs related thereto; require several individual process and handling steps which create defects and lower wafer yields; damage to the wafer from charge effects in RF-based plasma ashers; damage to the wafer from corrosive chemical etching of oxide due to the use of halogen gas such as fluorine; damage the wafer from the use of high temperatures in ashing (e.g., wafer warp and/or changes in dopant levels which take the devices outside their intended electrical specifications), etc. In addition, plasma ashers and wet benches may be incompatible with certain wafer types, such as very porous layers such as low k films, as the chemicals become trapped in the porous film.

In view of the limitations of the prior art, it is highly desirable to have a method in the art for the removal of ion implanted resist that addresses the problems mentioned above. A new method is therefore needed in the art that permits removal of the resist with a much simpler, safer, and more economical method, features that will reduce defects and improve yields, and enable an economical process for future devices that incorporate higher speed films such as low k materials.

A new method is needed in the art that would also avoid temperatures of 100° C. or higher to prevent thermal damage such as wafer warp and prevent the movement of dopants in the wafer structure. A new method is needed in the art that can be operated room temperature with wide process latitude, avoiding the need to have critical temperature control for heating or cooling.

In addition, a new method is needed in the art that would have low cost of ownership with respect to both equipment and consumables and can avoid the use of hazardous or corrosive acids, solvents and other chemicals that create safety and waste treatment problems. Examples of these materials include all halogen gases such as fluorine and strong acids such as hydrofluoric and hydrochloric acids and alkaline materials such as ammonium hydroxide. These materials are widely used currently in the prior art, conventional resist removal methods; the processes they are part of are also widely used throughout the IC industry.

A new method is needed in the art that is non-damaging to the substrate, eliminating the loss of substrate oxide thickness and charging of the wafer associated with RF ashing process and wet bench, corrosive chemical baths. A new method is needed in the art that will not leave any detectable residues, avoiding the current art of adding extra process steps to remove residues left by plasma ashing processes.

Finally, a new method is needed that will operate in a relatively simple, small footprint, automated single wafer system with reduced handling, wide process latitude to minimize expensive process control measures, and low facility infrastructure requirements. The combination of these parameters is needed to provide a low cost of ownership tool, necessary for competitive, viable manufacturing processes.

### SUMMARY OF THE INVENTION

The primary object of the present invention is a process for stripping resist after high dose ion implantation.

It is a further object of the present invention to remove ion implanted resist with a simple process.

It is a further object of the present invention to provide high throughput rates.

It is a further object of the present invention to provide a low temperature process.

It is a further object of the present invention to provide a method with low cost of ownership.

It is a further object of the present invention to provide a method that eliminates the need for using corrosive and hazardous materials.

It is a further object of the present invention to provide a method that is non-damaging to the substrate.

It is a further object of the present invention to provide a method that does not leave carbon crust particles or residues requiring subsequent wet corrosive chemical processing that etches oxide or otherwise damages the substrate.

This invention results from the discovery and realization that a laser beam and certain gases can be used to completely remove ion implanted resist without damaging the wafer, with a very simple, dry process, with acceptable throughput rate, that can be operated at room temperature with wide process latitude. Since the laser beam uses low energy photons that do not cause damage, particularly when kept below the fluence damage threshold of the substrate or film being exposed, there is wide latitude for the process, and very good control over removing thin layers such as ion implant crust. Since the crust of the implanted resist is darker than the unreacted resist, photons from the laser are more strongly absorbed in the surface of the crust. As a result, the crust can be controllably removed by the laser beam and gas without causing popping. Since the method only uses a laser beam and a gas or gas mixture, the problem of using corrosive wet processing that damages the substrate is eliminated. Since the process takes place in a small footprint, low vacuum, simple automated system without the need for complex facility infrastructure, the cost of ownership is low. Since the photoreactive process of the present invention uses the principles of photoablation in which intense surface absorption and heat are confined to a thin surface layer, by products are ejected and removed at high speeds directly away from the wafer surface, eliminating the problem of residues. Since the UV absorption is highly confined to a thin portion of the surface, and does not penetrate into the bulk of the resist film, the process is highly controllable and largely athermal, eliminating the problem of overheating and radiational damage to the silicon wafer.

According to one aspect, this invention features a small solid state laser, beam conditioning optics that expand, anamorphically correct, and flatten the beam by reducing the inherent intensity variation before sending it through an optical scanning head, where the beam is directed through a quartz window and into the process chamber. The wafer is loaded by a robot through a computer controlled chamber door, and placed onto the vacuum chuck. When the door closes, the laser beam scans the wafer surface while a gas is simultaneously introduced into the chamber such that the gas and laser light interact with the resist, causing the resist to be controllably removed. A reducing gas may be used with the laser beam to controllably remove the carbon crust, and a second oxidizing gas may be used with the laser beam to remove the remaining unreacted photoresist. The use of an aluminum chamber in this method permits the removal of ionic charges in the gas stream before they contact the wafer. This feature prevents electrical charging damage to devices on the wafer.

The by products of the process are drawn off into the exhaust system. At the end of the cycle, the beam and gas are shut off, the chamber door opens, and the robot removes the wafer into a cassette, and takes another wafer from the cassette, and repeats the cycle. A complete cycle may take in the range of one to three minutes, depending on the type of resist, the level of ion implantation, and other process variables that are generally optimized for a given sample.

In an implementation of the present invention, an optical module is provided that performs the optical function of expanding and flattening the laser beam. The beam expander and beam flattener can be used as individual optical modules, or integrated into a single expander/flattener module. The expansion and flattening of the beam removes the low intensity areas of the beam on its sides, called the ‘shoulders’, as well as the high intensity area in the center. A beam of high uniformity is produced that is needed to clean many thin semiconductor films without damage to the substrate. For example, very thin oxides and delicate and porous low k films require highly uniform laser beam energy to completely remove the resist films without damaging the substrate.

By fully reacting the entire area of the wafer to a given pulse or series of pulses of the beam, less overlap is required to clean the wafer, significantly increasing the throughput of the cleaning system of the present invention. In one embodiment consistent with the principles of the invention, software program is provided that optimally arranges the pulses for a highly efficient multiple scan method that will also spread out the landing of the pulses on the resist or substrate surface to reduce the total thermal load on any given spot. In an exemplary preferred embodiment, the strategic placement of laser pulses and rows of pulses, alternately and non-adjacently in space and time, is used to provide a method of cleaning a surface that would ordinarily be damaged by simply scanning abutting rows of pulses sequentially across a surface.

In another implementation, the beam flattener and beam expander, or beam flattener/expander module permits the use of a lower power laser. A series of experiments were conducted to determine the cleaning threshold, or the lowest possible energy per unit area in a given pulse needed to remove resist. The results of these experiments showed that by decreasing the diameter of a low power laser beam, this threshold energy per unit area can still be achieved. The beam flattening function is even more important when used in conjunction with a small, solid state laser as there is less available energy in a single pulse.

The beam flattener, and beam flattener/expander modules, as an addition to the existing optical system and method of the present invention, extends the capability to clean more porous and delicate thin semiconductor films such as low k films, and at the same time increased the throughput or parts per hour processed with the present invention. The higher throughput provides lower cost of ownership, another object of the present invention.

The method of the present invention uses the beam flattening optics module, which reduces the intensity variation in the beam significantly, to achieve good wafer throughput, and at the same time, remove the peak intensity profile of the raw laser beam to prevent damage to the wafer.

Other objects and further features and advantages of the present invention will be apparent to those skilled in the art from the following detailed description when read in conjunction with the accompanying drawings and claims.

### BRIEF DESCRIPTION OF THE DRAWINGS

The accompanying drawings, which are incorporated in and constitute a part of this specification, illustrate one or more embodiments of the invention and, together with the description, explain the invention. In the drawings,

FIG. 1 illustrates a cross-section of an ion implanted resist layer on a semiconductor silicon wafer;

FIGS. 2A-2L illustrate exemplary implementations to remove the ion implanted resist from a surface;

FIG. 3 illustrates exemplary prior art processing to remove ion implanted photoresist;

FIGS. 4A-4E illustrate exemplary process flow implementations to remove ion implanted photoresist from substrates;

FIG. 5 illustrates a table of x-ray photoelectron spectroscopy analytical results related to a wafer sample after the wafer is subjected to an ozone/oxygen technique for ion implant resist removal;

FIG. 6A illustrates an exemplary atomic force microscope analysis result for an uncoated control wafer;

FIG. 6B illustrates an exemplary AFM analysis result for a coated wafer that is cleaned using an exemplary implementation;

FIG. 7 illustrates an exemplary implementation that can be used to remove ion implanted resist from a surface of a wafer; and

FIG. 8 illustrates an exemplary implementation of a cluster tool that cleans a substrate using laser radiation and gas.

### DETAILED DESCRIPTION OF PREFERRED EMBODIMENTS

The following detailed description of implementations consistent with the principles of the invention refers to the accompanying drawings. The same reference numbers in different drawings may identify the same or similar elements. Also, the following detailed description does not limit the invention. Instead, the scope of the invention is defined by the appended claims and their equivalents.

An implementation consistent with the principles of the invention may use a solid-state laser and a gas mixture to remove ion implanted resist 105 without damaging a wafer surface. The implementation may remove the resist without producing hazardous by products, using liquid solutions, abrasive materials, high temperatures (e.g., temperatures greater than 100 degrees centigrade), etc.

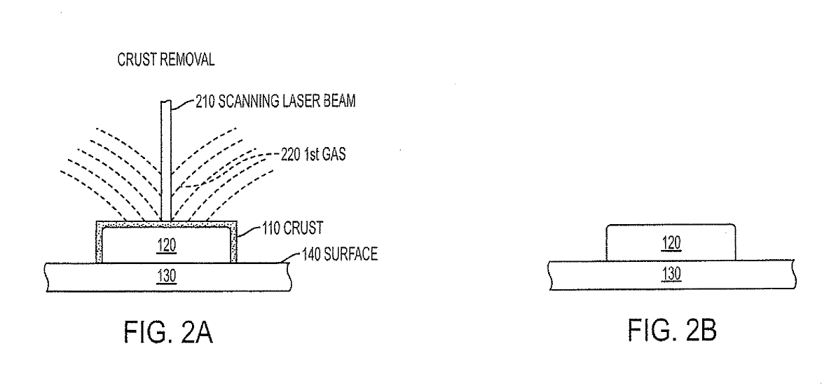

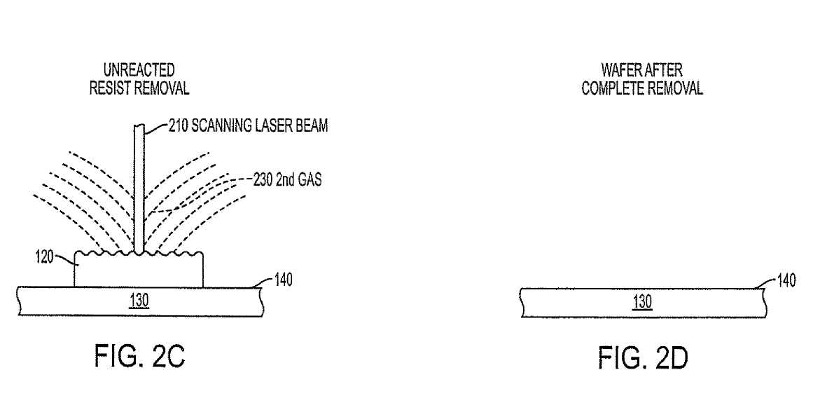

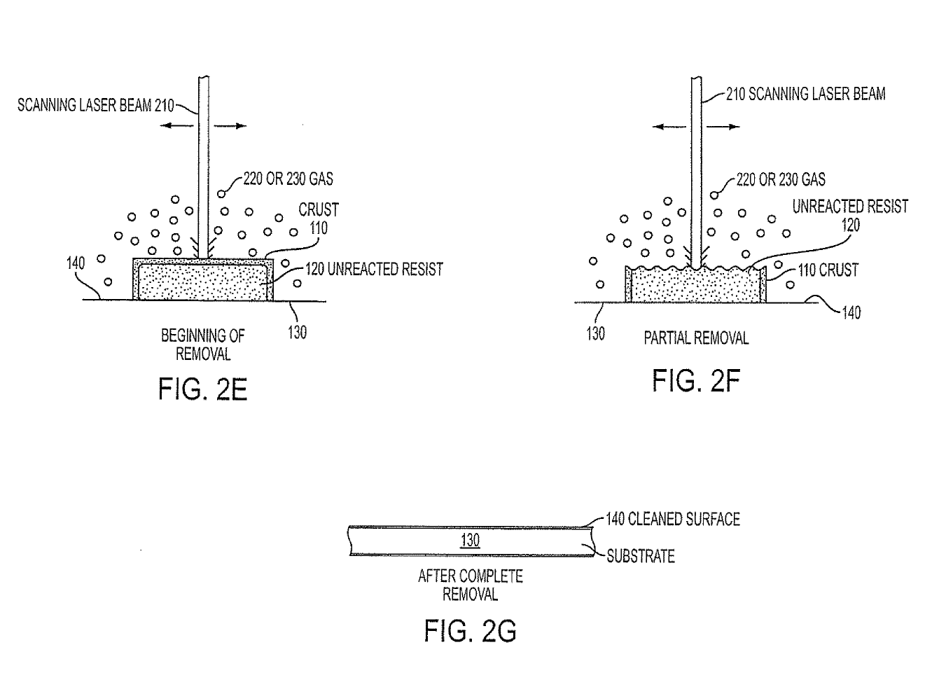

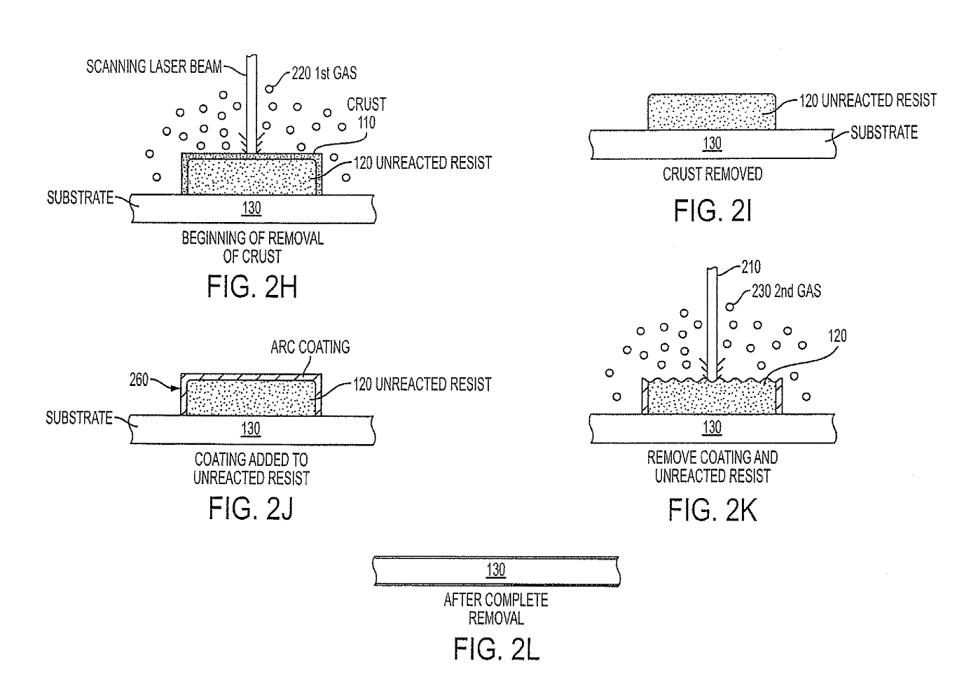

For example, in FIGS. 2A-L, a 10 watt solid-state laser may output a beam 210 with a wavelength on the order of approximately 355 nanometers (nm). The beam may illuminate resist having an upper crust 110 and an unreacted lower surface 120. The beam should have a fluence in the range of 50 to 500 milliJoules per square centimeter (mJ/cm²), and should also be lower than the fluence required to remove the unreacted lower resist. The beam is more strongly absorbed by the crust since the crust is darker than the lower photoresist. Absorption of the beam allows the crust to be removed (e.g., via a photochemical ablative mechanism) without popping (a process that occurs when solvents in the lower resist burst through the crust and deposit hot particles of crust onto the surface of the wafer), since the lower photoresist is essentially left untouched.

Implementations may occupy a small footprint and may use small amounts of power as compared to other semiconductor cleaning processes. For example, an implementation may be used to clean wafers at room temperature, thus alleviating the need for wafer heating devices. Implementations may further be automated so that risks of wafer contamination are minimized. Implementations may further clean wafers at a rate amenable to use in semiconductor manufacturing facilities (e.g., on the order of 3 minutes or less per wafer). Implementations can further be adapted to work in tool arrangements, such as cluster tool arrangements.

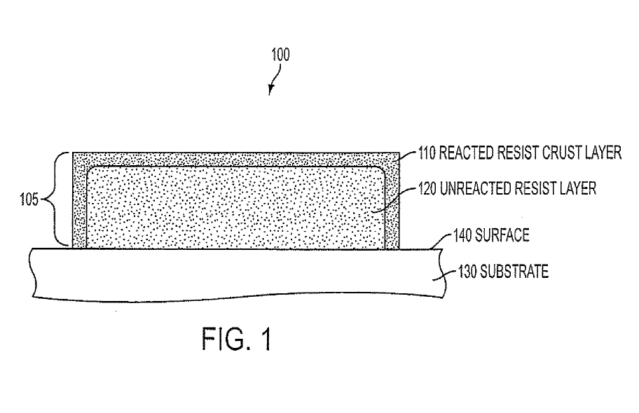

FIG. 1 illustrates a cross-section of arrangement 100 including an ion implanted resist layer on a semiconductor silicon wafer. Arrangement 100 may include implanted resist 105 that includes a reacted resist crust layer 110 (hereinafter crust 110) and an unreacted resist layer 120 (hereinafter unreacted layer 120), a substrate 130, and a surface 140.

Crust 110 may include a region of densified resist (i.e., a portion that is compacted with respect to another portion of resist, such as unreacted layer 120). Crust 110 may include carbonized material that may be hard and brittle with respect to unreacted layer 120. Crust 110 may include other materials, such as solvents, metals, chemicals, etc. As described briefly above, crust 110 may be capable of re-depositing on a surface of substrate 130 when crust 110 is heated and/or removed using certain techniques. Crust 110 that re-deposits on a surface of substrate 130 may be difficult to remove without damaging a surface 140 of substrate 130. In one implementation, crust 110 may be formed when a coated substrate is subjected to ion implantation. In one implementation, crust 110 may be formed by high dose ion implantation, e.g., ion implantation having doses in the range of 5×10¹⁶ atoms/centimeter squared (atoms/cm²).

Unreacted layer 120 may include resist that has not been reacted, such as by being exposed to ions related to an ion implantation process. Characteristics of unreacted layer 120 may differ from those of crust 110, e.g., unreacted layer 120 may have a lower density as compared to crust 110, may be less brittle as compared to crust 110, may be easier to remove from surface 140 than crust 110, may have a significantly higher solvent content, etc.

Substrate 130 may include a semiconductor wafer, such as a low-k wafer, and/or other types of wafers used in semiconductor related arts. In other implementations, substrate 130 may include compact disks, thin film heads, etc.

Surface 140 may include a portion of substrate 130, such as an upper surface on which circuit patterns, contaminants, coatings, etc. can reside. Surface 140 may be flat, curved, layered, and/or may have other shapes.

FIGS. 2A-L illustrate exemplary techniques to remove ion implanted resist 105 from surface 140. FIG. 2A may illustrate crust 110, unreacted layer 120, substrate 130, beam 210, and first gas 220. Crust 110, unreacted layer 120, and substrate 130 may be configured as described in connection with FIG. 1.

Beam 210 may include electromagnetic energy that can be deposited on a target. For example, beam 210 may include a laser beam that can be directed to a target area, such as a portion of crust 110, unreacted resist 120, surface 140, etc. In one implementation, beam 210 may be moveable across surface 140, i.e., beam 210 can be scanned across surface 140 so that substantially all of surface 140 (or contaminants on surface 140) is exposed to beam 210. Beam 210 may further be controlled (e.g., may be shaped) via optical components (e.g., collimators, splitters, beam flatteners, etc.).

In one implementation, beam 210 may be produced via a solid-state laser (not shown). The solid-state laser may be on the order of a 10-watt laser and may output electromagnetic energy at wavelengths in the range of about 150 nanometers (nm) to about 580 nm. The electromagnetic energy may be delivered to ion implanted resist 105 via pulses. In one implementation, pulses having energies in the range of 0.1 to 1.5 milliJoules (mJ) per pulse may be used. Pulses may have pulse energy densities in the range of 15 mJ/cm² to 1,100 mJ/cm² in one implementation.

Beam 210 may pass through optical elements (not shown) that condition beam 210 (e.g., by expanding the beam, flattening the beam, anamorphically correcting the beam, etc.). For example, beam flattening optics may operate to reduce an intensity variation of beam 210, where the intensity variation may be a function of a location within an area illuminated via beam 210. The optical elements may further scan beam 210 (e.g., via an optical scanning head) and may direct beam 210 to a quartz window that covers a chamber that contains substrate 130 and/or one or more gases, such as reaction gases that facilitate removal of ion implanted resist 105.

In one implementation, an optical module (not shown) may be configured to removably interact with other components in an optically based cleaning system. The optical module may includes a beam expander/flattener, where the expanding/flattening of beam 210 removes low intensity areas related to side portions of beam 210 (e.g., shoulders of the beam). The beam expander/flattener may further reduce high intensity regions that may occur near a center portion of beam 210. The beam expander/flattener may create a substantially uniform intensity at a surface (e.g., an upper surface of ion implanted resist 105). A flattened beam 210 may further react resist over a larger area as compared to an area of resist that may be reacted via an unflattened beam 210. In one implementation, flattened beam 210 may react substantially an entire illuminated area of ion implanted resist 105. Use of a flattened beam 210 may allow surface 140 to be cleaned of ion implanted resist 105 at a faster rate as compared to a cleaning rate when a non-flattened beam 210 is used.

For example, in one implementation, an expanded/flattened beam 210 may be scanned across surface 140 in a manner whereby substantially all ion implanted resist 105 is reacted in the presence of one or more gases to remove the ion implanted resist 105 without damaging surface 140. The expanded/flattened beam 210 may reduce thermal loads on an area illuminated via beam 210 as compared to a thermal load on the same area when beam 210 is not expanded/flattened and/or scanned. Scanning patterns may be determined via machine readable instructions implemented via logic (e.g., code) such that sequential pulses do not overlap. In one implementation, pulse overlap for complete coverage of surface 140 may be achieved by multiple scans, or passes of beam 210 over surface 140. Expanded/flattened beams 210 may allow an implementation to be used to clean sensitive substrates 130, such as porous substrates, e.g., low-k substrates.

First gas 220 may include an oxidizing gas, a reducing gas, and/or another gas that can be used with beam 210 to remove a portion of ion implanted resist 105 from surface 140. In one implementation, gas 220 may be oxygen and/or ozone gas in a concentration on the order of 4% to 20% by volume. In another implementation, a reducing gas (e.g., hydrogen, ammonia, hydrides, hydrocarbons, etc.) may be used. In other implementation, oxidizing gases may be used (e.g., oxygen, ozone, hydrogen peroxide vapor, halogen, etc.) and/or other gases, such as enhancing gases. Other implementations may use inert gases and/or water vapor alone or with reducing and/or oxidizing gases.

FIG. 2A illustrates ion implanted resist 105 with crust 110 removed via beam 210. For example, beam 210 may be delivered from a solid-state neodymium-doped yttrium aluminum garnet (YAG) laser having an output wavelength on the order of 355 nm. Beam 210 may be delivered in the presence of a reducing gas and may remove crust 105 while leaving unreacted layer 120 substantially intact. Crust 110 may be photoablated from surface 140 via beam 210 and the reducing gas. In an implementation, portions of crust 110 (e.g., relatively small particles) may redeposit onto surface 140. These redeposited particles are not thermally adhered to surface 140 and may be removed via a simple alcohol and/or deionized water rinse process.

FIG. 2C illustrates beam 210 contacting a portion of unreacted layer 120 in the presence of a second gas. Beam 210 may illuminate a portion of unreacted layer 120 in the presence of a second gas, such as an oxidizing gas and/or a reducing gas. For example, in one implementation, beam 210 may operate in the presence of ozone having a concentration in the range of 4% to 20% by volume. The ozone may be mixed with one or more other gases in an implementation. For example, ozone may be mixed with oxygen and/or water vapor. Beam 210 may remove unreacted layer 120 from surface 140.

FIG. 2D illustrates surface 140, where surface 140 is substantially free of ion implanted resist 105. Surface 140 may be rinsed and dried and substrate 130 may be further processed in accordance with semiconductor manufacturing techniques practiced in the relevant arts.

FIG. 2E illustrates a single step ion implanted resist 105 removal technique. In FIG. 2E, beam 210 may remove crust 110 and unreacted resist 120 in a single pass. FIG. 2E shows beam 210 in the presence of first gas 220 and/or second gas 230.

FIG. 2F shows beam 210 photoablating unreacted resist 120 in the presence of first gas 220 or second gas 230. FIG. 2G shows a clean and undamaged substrate 130 after cleaning by a single step technique.

FIG. 2H illustrates a multi step technique for removing ion implanted resist 105. Beam 210 may illuminate crust 110 in the presence of first gas 220 or second gas 230. FIG. 21 shows unreacted resist 120 after crust 110 has been removed. In FIG. 2J, unreacted resist 120 is coated with an anti-reflective coating (ARC) 260. In FIG. 2K, beam 210 illuminates ARC 260 and unreacted resist 120 in the presence of second gas 230. FIG. 2L illustrates a cleaned substrate 130.

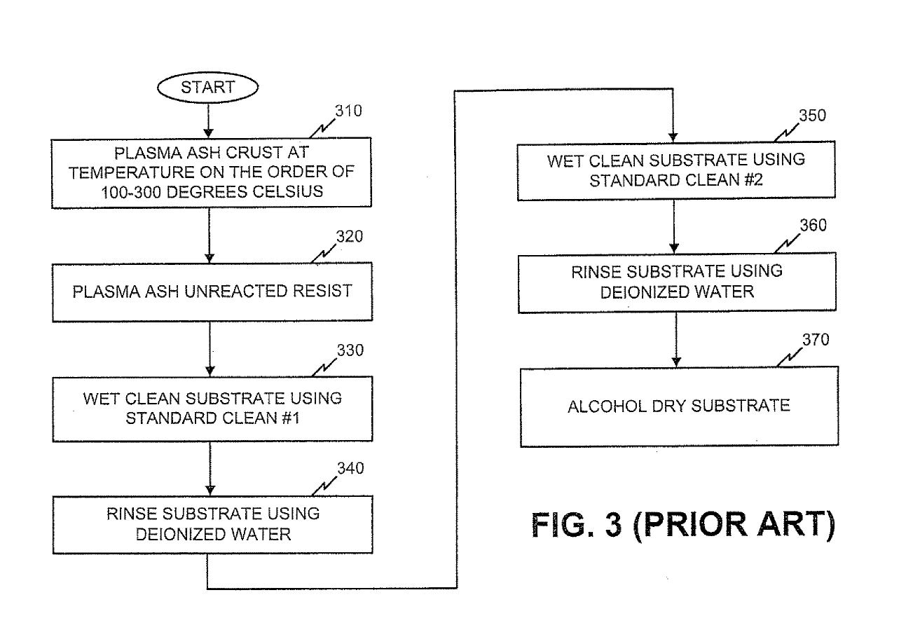

FIG. 3 illustrates exemplary prior art processing to remove ion implanted photoresist. In FIG. 3, blocks 310 and 320 may occur in a plasma asher tool as used in the relevant art. Blocks 330 to 360 may occur in a wet bench tool used in the relevant art, and block 370 may occur in a dryer tool as used in the relevant art. As a result, several complex and expensive pieces of equipment are required to clean a wafer (substrate) using prior art techniques. In addition, prior art techniques may roughen a surface of the wafer, thus degrading performance of a finished wafer. Moreover, prior art techniques, as shown in FIG. 3, may not clean certain types of wafers, such as porous wafers without damaging the wafers to a degree that make wafer yields unacceptably low.

Referring to FIG. 3, an ion implanted resist crust may be plasma ashed in a plasma asher tool at a temperature on the order of 100 degrees Celsius (° C.) to 300° C. (block 310). Unreacted resist may be plasma ashed at temperatures on the order of 100° C. or more (block 320). A wafer may be wet cleaned using standard clean #1, or other compatible cleaning solution, in a wet bench tool (block 330). The wafer may be rinsed with deionized water in the wet bench (block 340). After cleaning with deionized water, the wafer may be cleaned in the wet bench using standard clean #2 and/or another compatible cleaning solution (block 350). The wafer may be cleaned using another deionized water rinse in the wet bench (block 360). The cleaned wafer may be alcohol dried in a drying tool (block 370).

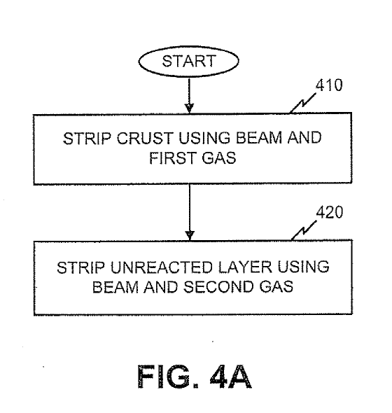

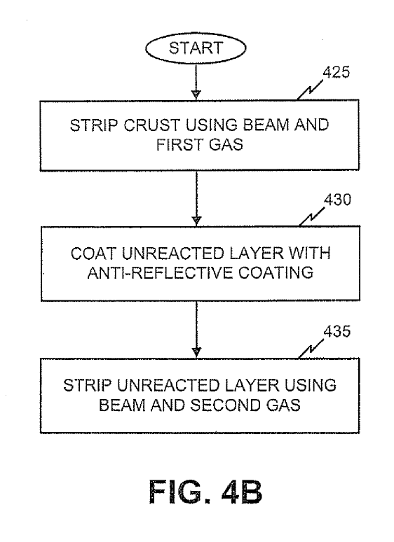

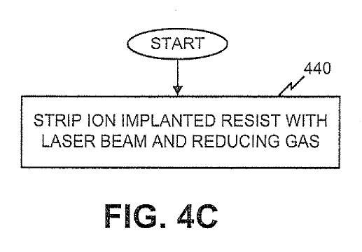

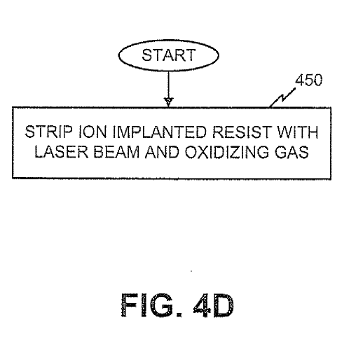

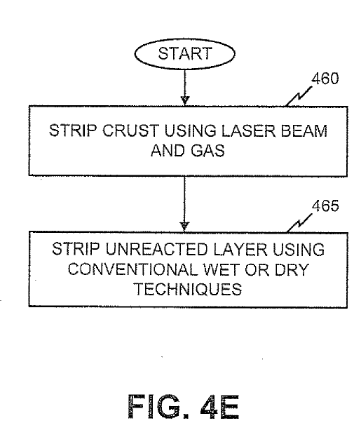

FIG. 4A illustrates exemplary processing to remove ion implanted photoresist using an exemplary implementation. Beam 210 may be used to illuminate a portion of ion implanted resist 105 in the presence of a gas, such as hydrogen, ammonia, ozone, etc. (block 410). In one implementation, beam 210 may be scanned across surface 140 in a first pass to remove crust 110.

Beam 210 may illuminate unreacted layer 120 in the presence of a second gas, such as hydrogen, ammonia, ozone, etc., to strip unreacted layer 120 from surface 140 (block 420). In one implementation, beam 210 may be scanned across surface 140 in a second pass to remove unreacted layer 120 when crust 110 has been removed from surface 140.

FIG. 4B illustrates alternative exemplary processing to remove ion implanted resist using an exemplary implementation. Blocks 425, and 435 of FIG. 4B may be similar to blocks 410 and 420 of FIG. 4A. The implementation of FIG. 4B may include an act whereby unreacted layer 120 is coated with a coating, such as an anti-reflective coating (block 430). For example, substrate 130 may be coated with a 355 nm absorbing polymer layer, such as an ARC layer. The ARC layer may be adhered to surface 140 via techniques, such as baking. For example, in one implementation, the ARC layer may be baked at a temperature in the range of approximately 110° C. for a determined time interval in the range of one minute.

The anti-reflective coating may be adapted to absorb light having a wavelength in the range of wavelengths used in beam 210 (e.g. 355 nm). The anti-reflective coating may retain particles that might otherwise become dislodged when unreacted layer 120 is photoablated from surface 130 via beam 210.

FIG. 4C illustrates exemplary processing for a single step technique to remove ion implanted resist. Ion implanted resist 105 may be illuminated via beam 210 in the presence of a reducing gas (block 440). Ion implanted resist 105 is photoablated via beam 210 in the presence of the reducing gas.

FIG. 4D illustrates exemplary processing to remove ion implanted resist 105. Beam 210 may strip ion implanted resist 105 using beam 210 in the presence of an oxidizing gas (block 450).

FIG. 4E illustrates exemplary processing to remove ion implanted resist 105. Crust 110 may be stripped using beam 210 in the presence of a gas, such as first gas 220 or second gas 230 (block 460). Unreacted resist 120 may be removed via non-optically based techniques and/or other techniques (e.g., plasma ashing) (block 465).

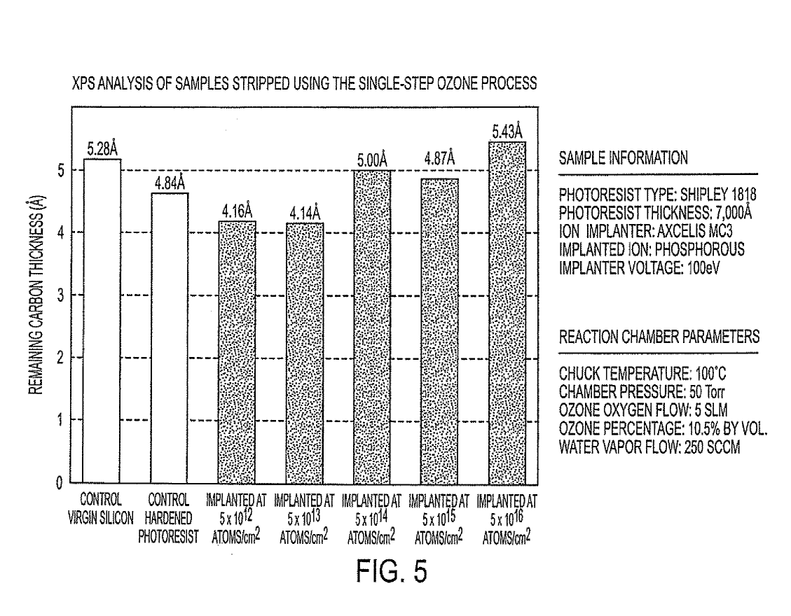

FIG. 5 illustrates a table of x-ray photoelectron spectroscopy (XPS) analytical results related to a wafer sample after the wafer is subjected to a single pass ozone/oxygen ion implant resist removal. The results illustrated in connection with FIG. 5 were achieved without rinsing or otherwise cleaning substrate 130 after the single pass.

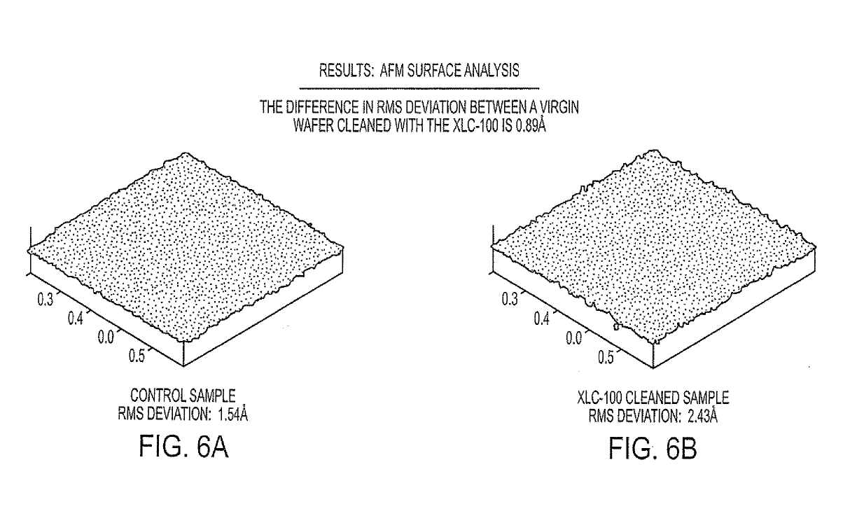

FIG. 6A illustrates an exemplary atomic force microscope (AFM) analysis result for an uncoated wafer. FIG. 6A may include a portion of surface 130 that is view under an atomic force microscope (AFM). As illustrated in FIG. 6A, a control sample (i.e., a sample that has not been processed and/or coated) may have a surface roughness on the order of 1.54 angstroms (Å).

FIG. 6B illustrates an exemplary AFM analysis result for a coated non-ion implanted wafer that includes a portion of surface 130 that has been cleaned using an implementation (e.g., where ion implanted resist 105 has been removed via beam 210).

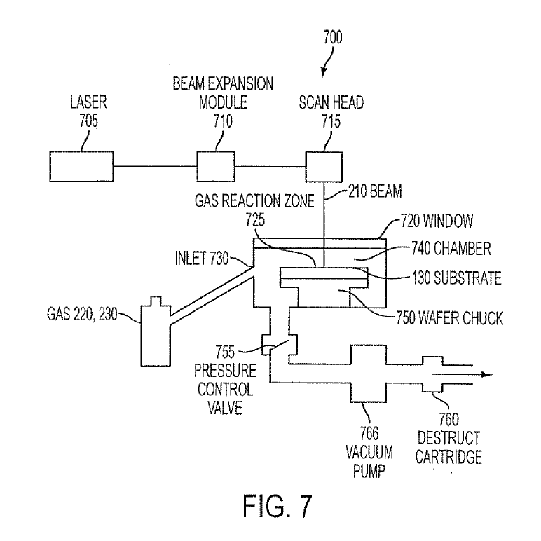

FIG. 7 illustrates an exemplary implementation of a system 700 that can be used to remove ion implanted resist from a surface of a wafer. System 700 may beam 210, gas 220/230, laser 705, beam expansion/flattener module 710, scan head 715, window 720, reaction chamber 725, gas inlet 730, chamber 740, wafer chuck 750, pressure control valve 755, vacuum pump 760, and destruct cartridge 765. The implementation illustrated in connection with FIG. 7 is exemplary and other implementations may include more components, fewer components, and/or components in arrangements other than the arrangement of FIG. 7.

Substrate 130, beam 210 and gas 220/230 may be similar to substrate 130 described in connection with FIG. 1 and beam 210 and gas 220/230 described in connection with FIG. 2. Laser 705 may include a device that produces electromagnetic radiation. In one implementation, laser 705 may be a pulsed solid-state YAG laser that outputs a wavelength on the order of 355 nm. In another implementation, laser 705 may include a solid-state laser that can output a wavelength in a range from 150 nm to 580 nm. In still other implementation, laser 705 may be a non-solid state laser and may output other suitable wavelengths.

Beam expansion/flattening module 710 (hereinafter beam module 710) may include an optical device that expands and/or flattens an incoming beam. For example, beam module 710 may include optical components that receive a circular beam having a first intensity in a middle portion and a second intensity in an edge portion. Beam module 710 may increase a diameter of the beam and may flatten the first intensity with respect to the second intensity, whereby the difference between the first intensity and second intensity is smaller at an output of beam module 710 than at an input of beam module 710. Implementations may employ beam expansion/flattening modules 710 adapted to expand/flatten beam 210 in a single dimension (e.g., in one plane) and/or in multiple dimensions (e.g., more than one plane).

Scan head 715 may include a device that causes beam 210 to move from a first location on surface 140 to a second location on surface 140. For example, scan head 715 may be controlled via a controller that causes scan head 715 to sweep beam 210 across surface 140 according to determined criteria, such as a predetermined scanning pattern. Scanning patterns may include overlapped and/or non-overlapped patterns or may include several scans to create overlap with no overlap in a single scan. Scanning patterns may further include steady state scan patterns, where beam 210 is moved at a constant speed across surface and/or non-steady state scanning patterns where beam 210 is moved at varying rates across surface 140.

Window 720 may include a device that allows electromagnetic energy to pass from a first side (e.g., an upper side facing scan head 715) to a second side (e.g., a lower side facing an upper surface of substrate 130). In one implementation, window 720 may be made of quartz. Implementations of window 720 may have one or more surfaces coated with an antireflective coating. Implementations of window 720 may be adapted to operate with chamber 740 to form a local environment around substrate 130. For example, window 720 and chamber 740 may form a reaction chamber that can be pressurized (i.e., a pressure that exceeds an ambient pressure around system 700) and/or can have a vacuum applied thereto (i.e., a pressure in the reaction chamber is less than an ambient pressure around system 700).

Gas reaction zone 725 may include a region proximate to where beam 210 contacts ion implanted resist 105 and/or surface 140. For example, gas reaction zone 725 may include a volume where portions of crust 110 are photoablated from surface 140. In one implementation, gas reaction zone 725 may include one or more gases, such as hydrogen, ozone, ammonia, etc.

Gas inlet 730 may include a device to deliver one or more gases to chamber 740. In one implementation, gas inlet 730 may be a nozzle, a duct, a valve, etc. Gas inlet 730 may be adapted to allow a constant (e.g., even or steady state) flow to reach chamber 740. Chamber 740 may include a device that maintains an environment around substrate 130 while substrate 130 is cleaned. Chamber 740 may be made of metal (e.g., aluminum, steel, titanium, etc.), plastic, composite, and/or other material. In one implementation, a metal chamber 740 may have a charge applied thereto to draw gases and/or materials thereto and/or to repel gases and/or materials therefrom. For example, an aluminum chamber 740 may allow for removal of ionic charges in the gas stream before the gas stream contacts substrate 130. Removal of ionic charges may prevent electrical charging damage to devices on the wafer. Chamber 740 may be sealed when substrate 130 is placed in chamber 740 so an interior region containing wafer 130 can be pressurized (i.e., pressure above an ambient pressure around system 700) or can have a vacuum drawn thereupon (i.e., a pressure below an ambient pressure around system 700)

Wafer chuck 750 may include a device to maintain substrate 130 in a determined position with respect to other components in system 700. For example, wafer chuck 750 may hold substrate 130 in a position with respect to scan head 715, window 720, etc. Implementations of wafer chuck 750 may be heated or cooled and/or fixed in place or moveable.

Pressure control valve 755 (hereinafter control valve 755) may include a device that controls a pressure (e.g., an environmental pressure, a gas pressure, etc.). In one implementation, control valve 755 may maintain a pressure in chamber 740 at a determined value (e.g., at a determined number of pounds per square inch above or below a pressure around system 700).

Vacuum pump 760 may include a device that can draw a vacuum on an interior region of chamber 740. For example, vacuum pump 760 may maintain chamber 740 at a negative pressure with respect to an ambient pressure around system 700.

Destruct cartridge 765 may include a device that can change a composition of an incoming gas mixture. For example, destruct cartridge 765 may filter particles from an outgoing gas flow (e.g., a gas flow exiting chamber 740), may convert volatile gases and/or compounds into inert gases and/or compounds, etc.

An implementation, such as system 700, may clean substrates at a rate of approximately one wafer every 90 to 120 seconds. For example, system 700 may strip a coating on the order of 1.3 microns thick in about 90 seconds. System 700 may be implemented in a number of embodiments to clean substrate 130. For example, implementations may use different wavelengths of electromagnetic energy, different pulse shapings, pulse energies, pulse repetition rates, pulse widths, gas mixtures, chamber pressures, substrate temperatures, etc. A first exemplary implementation of system 700 may include a gas mixture having ozone at a concentration on the order of 10.5%, a gas flow on the order of 5 standard liters per minute (slm), a chamber pressure on the order of 50 Torr, a substrate temperature on the order of 90° C., a solid-state laser outputting a wavelength on the order of 355 nm, a laser power on the order of 9 Watts, and a laser pulse energy on the order of 0.9 mJ.

The first exemplary implementation may remove ion implanted resist 105 in a single pass (i.e., crust 110 and unreacted layer 120 are removed at substantially the same time). The first exemplary implementation may be used to remove high dose implants on the order of 5×10¹⁶. For example, the high dose resist can be removed without damaging surface 140.

A second exemplary implementation of system 700 may include the use of a hydrocarbon-containing gas, such as hydrogen. The hydrocarbon-containing gas may include a second oxidizing gas to remove an underlying portion of unreacted layer 120 since unreacted layer 120 may not be hardened by the implant process.

The second exemplary implementation may include a gas mixture having ozone at a concentration on the order of 12% in Argon, a gas flow on the order of 500 standard cubic centimeters per minute (sccm), a chamber pressure on the order of 5 Torr, a substrate temperature on the order of 30° C., a solid-state laser outputting a wavelength on the order of 355 nm, a laser power on the order of 10 Watts, and a laser pulse energy on the order of 1.0 mJ at 10 kHz.

In one experiment, the second implementation was shown to remove approximately a 1.0 micrometer thick layer of Shipley 1818 positive resist.

In a third example, the process may begin with 100% H₂ at a low fluence to remove crust 110. The fluence may be lower that a fluence used to remove unreacted resists.

A third exemplary implementation of system 700 may be operated with an oxidizing gas to remove unreacted layer 120. The gas mixture may contain oxygen and may have a gas flow on the order of 9000 standard cubic centimeters per minute (sccm) A chamber pressure on the order of 130 Torr may be used with a substrate temperature on the order of 90° C. A solid-state laser outputting a wavelength on the order of 355 nm, having a laser power on the order of 10 Watts, and a laser pulse energy on the order of 0.89 mJ may illuminate the resist.

A fourth exemplary implementation of system 700 may be operated with a gas that includes NH₃, a gas flow in the range of 400-2000 sccm standard cubic centimeters per minute (sccm), a chamber pressure on the order of 25-100 Torr, a substrate temperature on the order of 25-30° C., a solid-state laser outputting a wavelength on the order of 355 nm, a laser fluence in the range of 100-500 mJ/cm²/pulse.

A fifth exemplary implementation may achieve substantially the same results over a wide range of substrate temperatures, such as substrate temperatures from 5° C. to 30° C. The laser and the second gas are used to remove the ARC and the remaining unreacted photoresist under the ARC.

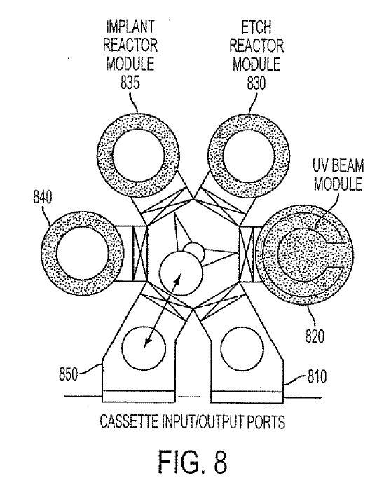

FIG. 8 illustrates an exemplary implementation of a cluster tool 800 that cleans a substrate using beam 210. Tool 800 may include input port 810, UV beam module 820, etch reactor module 830, implant reactor module 835, cool down module 840, and output port 850.

Input port 810 may include a device that accepts substrate 130. For example, input port 810 may accept substrate 130 having ion implanted resist 105 deposited on surface 140.

UV beam module 820 may include one or more devices to remove ion implanted resist 105 from surface 140. In one implementation, UV beam module 820 may include components of system 700. Etch reactor module 830 and implant reactor module 835 may operate on cleaned substrate 130 prior to cool down module 840. Cool down module 840 may include one or more devices to cool substrate 130 after substrate 130 passes through reactor modules 830 and 835. Output port 850 may include a device that sends substrate 130 to a destination.

Still other implementations may use other components, gases, and/or parameters to perform damage free cleaning of substrate surfaces.

Examples are presented herein below to illustrate exemplary implementations. The examples are representative and should not be construed as limiting.

### EXAMPLE I

An experiment was performed as follows: several samples consisting of wafers (hereafter samples) coated with approximately 7,000 Å of Shipley 1818 photoresist were ion implanted at doses of 5×10², 5×10¹³, 5×10¹⁴, 5×10¹⁵, and 5×10¹⁶ atoms per square centimeter. A control sample (hereafter control) consisting of 7,000 Å of Shipley 1818 photoresist was also prepared. The samples were all cleaned using the following process: The wafers were each placed in a chamber where the chuck was at a temperature of 100 degrees centigrade and pumped down to vacuum (approximately 1 Torr). A primary gas consisting of 10.5% (by vol.) ozone in oxygen was introduced into the chamber at a flow rate of 5 SLM along with a second gas consisting of 100% water vapor at a flow rate of 250 SCCM. The chamber was brought to a pressure of 50 Torr. The wafers were scanned using a 355 nm solid-state laser with an energy density at the surface of the wafer in the range of 400-1,000 mJ/cm² per pulse.

In this experiment, a single step process and a single gas were used to remove the entire photoresist layer, including removal of high dose implants of 5×10¹⁶. The results of XPS surface analysis from this experiment are shown in FIG. 5. The surface of the wafer was cleaned without detectable damage to the wafer surface, and there were no residues remaining. This exemplary implementation did produce shattering and break up of the crust layer, resulting is crust portions being deposited on the sidewalls of the chamber. A portion of the crust further landed on the wafer. These particles (crust portions) are not thermally adhered to the wafer, and processing the wafer in a simple rinser-dryer module, may result in a clean wafer surface.

In prior art processes, crust break-up is accompanied by considerable heating of crust particles, such that they land and stick to the wafer via thermal adhesion, a problem that requires the use of a complex wet bench cleaning process, including strong corrosive acids to break down the thermally reacted crust material.

### EXAMPLE II

An experiment was performed as follows: a sample consisting of a wafer coated with approximately 7,000 Å of Shipley 1818 photoresist was ion implanted at a dose of 5×10¹⁶ atoms per square centimeter. Areas of the sample were cleaned using the following process: The wafers were each placed in a chamber where the chuck was at a temperature of 30 degrees centigrade and pumped down to vacuum (approximately 1 Torr). A gas consisting of 12% (by vol.) hydrogen in argon was introduced into the chamber. Five sites on the wafer were scanned using a 355 nm solid-state laser with an energy density at the surface of the wafer in the range of 400-1,000 mJ/cm² per pulse. The scans were performed using the following gas flow rates and chamber pressures:

Site 1) Gas flow rate of 0.5 SLM and chamber pressure of 5 Torr;

Site 2) Gas flow rate of 2 SLM and chamber pressure of 100 Torr;

Site 3) Gas flow rate of 4 SLM and chamber pressure of 200 Torr;

Site 4) Gas flow rate of 6 SLM and chamber pressure of 300 Torr; and

Site 5) Gas flow rate of 8 SLM and chamber pressure of 400 Torr.

In this experiment an objective was to eliminate particles by increasing the reactive gas density, this was achieved by increasing the chamber pressure and flow. Good results were achieved at a flow rate of 8 SLM and a chamber pressure of 400 Torr. During this test the lower fluence reflective radiation removed the crust layer from the photoresist adjacent to the sample areas.

### EXAMPLE III

An experiment was performed as follows: a sample consisting of a wafer coated with approximately 7,000 Å of Shipley 1818 photoresist was ion implanted at a dose of 5×10¹⁵ atoms per square centimeter. Areas of the sample were cleaned using the following process: The wafer was placed in a chamber where the chuck was at a temperature of 30 degrees centigrade and pumped down to vacuum (approximately 1 Torr). A gas consisting of 100% hydrogen was introduced into the chamber at a flow rate of 8 SLM and the chamber was brought up to a pressure of 325 Torr. The wafer was scanned using a 355 nm solid-state laser with an energy density at the surface of the wafer in the range of 100-500 mJ/cm² per pulse. The above process substantially removed the upper crust layer from the ion-implanted photoresist, leaving the lower portion of the photoresist (e.g., unreacted portion of the photoresist) substantially intact.

An oxygen/ozone process was used on portions of the wafer to remove the lower portion of the photoresist once the upper crust was removed. The oxygen/ozone process was as follows: The wafer was placed in a chamber where the chuck was at a temperature of 90 degrees centigrade and pumped down to vacuum (approximately 1 Torr). A gas consisting of 10.5% (by vol.) ozone in oxygen was introduced into the chamber at a flow rate of 9 SLM and the chamber was brought up to a pressure of 130 Torr. The wafer was scanned using a 355 nm solid-state laser with an energy density at the surface of the wafer in the range of 400-1,000 mJ/cm² per pulse. This process removed the remaining photoresist (unreacted photoresist) leaving the wafer surface substantially free of carbon and substantially free of damage (i.e., no detectable surface roughening caused by the photoresist removal).

### EXAMPLE IV

An experiment was performed as follows: a sample consisting of a wafer coated with approximately 7,000 Å of Shipley 1818 photoresist was ion implanted at a dose of 5×10¹⁵ atoms per square centimeter. Areas of the sample were cleaned using the following process: The wafers were each placed in a chamber where the chuck was at a temperature of 30 degrees centigrade and pumped down to vacuum (approximately 1 Torr). A gas consisting of 100% ammonia was introduced into the chamber. Five sites were scanned using a 355 mm solid-state laser with an energy density at the surface of the wafer in the range of 100-500 mJ/cm² per pulse to remove the carbon crust. Scans were performed with the following gas flow rates and chamber pressures:

Site 1) Gas flow rate of 0.4 SLM and chamber pressure of 25 Torr;

Site 2) Gas flow rate of 0.8 SLM and chamber pressure of 50 Torr;

Site 3) Gas flow rate of 1.2 SLM and chamber pressure of 75 Torr;

Site 4) Gas flow rate of 1.6 SLM and chamber pressure of 100 Torr; and

Site 5) Gas flow rate of 2.0 SLM and chamber pressure of 100 Torr.

In this experiment it was determined that 100% ammonia gas works at a chamber pressure of 100 Torr. The ammonia gas appears to work as effectively as 12% hydrogen did at high pressures, such as 400 Torr.

### EXAMPLE V

In still another experiment, a wafer coated in 11,000 Å of Rohm & Haas UV1401, 248 nm DUV photoresist and ion implanted with phosphorous at a dose of 5×10¹⁵ atoms/cm². The wafer was placed in the chamber with the chuck temperature set at 30° C. and pumped down to vacuum (approximately 1 Torr). A gas comprised of 100% ammonia was flowed into the chamber at a rate of 8 SLM and the chamber was brought up to a pressure of 130 Torr. The wafer was scanned using a 355 nm solid-state laser with an energy density at the surface of the wafer in the range of 100-500 mJ/cm² per pulse to remove the carbon crust. Following this carbon crust removal step the wafer was coated with a layer of standard UV anti-reflection-coating (Brewer Science XHRiC-16ARC) and softbaked on a hotplate at 110° C. for one minute. The wafer was then processed through the standard oxygen/ozone process, as outlined in the exemplary embodiment above. The purpose of the ARC layer is to couple the laser beam energy more efficiently into deep UV resists, either 193 nm or 248 nm types, and permit more rapid and complete removal.

### SUMMARY

Experiments, such as those illustrated in the examples above, have shown that the process described herein can be performed with wide latitude. For example, the wafer temperature can be varied from 5 degrees centigrade to 30 degrees centigrade without substantially changing the resist removal rate or completeness of the carbon crust removal. It is expected that the temperature can be lowered below zero degrees centigrade without substantially changing the crust removal rate. The benefit of this is that preliminary experiments have indicated that while lowering the temperature has little to no effect on the crust removal rate, it does affect the reaction threshold of the lower, unreacted photoresist. If the lower portion of the photoresist can be prevented from reacting, popping can be eliminated, thus significantly reducing the number of particles landing on the wafer surface while adding more latitude in laser fluence.

Processes described herein further have wide latitude in the gas flow rate, chamber pressure, and gas composition parameters. The chamber pressure can be set anywhere from about 1 to 760 Torr, with gas flow rates anywhere from about 0.5 to 50 SLM. When selecting gas flow rates, it may be desirable to select a rate so as to match the chamber pressure (eg, at a pressure of 400 Torr is may be difficult to maintain with only 0.5 SLM of gas, and/or at a chamber pressure of 1 Torr may be difficult to maintain with 40 SLM of gas). The gas composition can be any reducing gas, or mixture of reducing gasses, such as hydrogen, ammonia, hydrazine, other hydrides, or hydrocarbons. The gas mixture may comprise of 100% reactive gas, or any mixture with an inert gas, such as nitrogen, argon, or helium, with a reactive gas concentration on the order of 4% or greater.

Laser energy density per pulse, also known as laser fluence, may be a parameter that is maintained within tolerances that are more restrictive than tolerances related to other parameters (e.g., gas flow, temperature, etc.). For each sample type there may be an optimum fluence range over which the process will work. This may vary with photoresist type, implant dose, and/or substrate reflectivity. As mentioned above, the reaction threshold of the lower photoresist layer is expected to decrease as the temperature is lowered, which offers greater latitude in laser fluence.

Finally, this process may also be used to remove the crust that forms on resist as a result of the etching process to make semiconductor devices. Certain etch gasses combine with the surface of the photoresist to form a tougher polymer. This tougher polymer is removable using the present invention.

Cost of ownership (CoO) analysis, based on the SEMATECH model used by major semiconductor chip makes, shows that the first year CoO for the conventional asher and wet bench tools used to remove ion implanted resist is $1,771,000.00, compared to a first year CoO of $635,400.00 for the present invention. There is a further cost savings realized by using a small footprint system of the present invention that does not require extensive facility air handling and extensive plumbing, nor costly waste treatment. Additionally, since the laser and gas process can be run at room temperature in a preferred embodiment, there may be no need for costly temperature control systems or loss of throughput waiting for the substrate to become warm or cool.

A major feature of the present invention is the use of gases versus the use of significant volumes of liquid chemicals and large volumes of highly purified water. The water cost is the largest single cost of most all IC cleaning processes in IC fabs. Added to this is the cost of waste treatment for chemical processes.

The footprint of the system used for the present invention is about 42 inches by 36 inches, where the footprint of a typical asher is about 48 inches by 96 inches, added to which is the typical footprint of a wet bench, being about 108 inches by 44 inches. The throughput of the present invention is about one 200 mm wafer every three minutes per clean, where the prior art method using an asher and wet bench produces about a wafer about every 9-12 minutes per clean.

What is claimed is:

1. A method for removing ion implanted photoresist from a surface of a substrate, the method comprising:
introducing a gas to a reaction chamber containing the substrate;
illuminating the ion implanted photoresist with radiation from a laser in the presence of the gas; and
scanning the radiation across the surface of the substrate in the presence of the gas to photoreactively remove the ion implanted photoresist from the surface of the substrate.

2. The method of claim 1, wherein the introducing comprises:
introducing an oxidizing gas.

3. The method of claim 2, wherein the introducing the oxidizing gas comprises:
introducing at least one of oxygen, ozone, hydrogen peroxide vapor, or a halogen.

4. The method of claim 2, wherein the introducing the oxidizing gas comprises:
introducing an enhancing gas.

5. The method of claim 4, wherein the enhancing gas comprises:
water vapor.

6. The method of claim 2, wherein the introducing the oxidizing gas further comprises:
combining the oxidizing gas with an inert gas.

7. The method of claim 1, wherein the introducing comprises:
introducing a reducing gas.

8. The method of claim 7, wherein the introducing the reducing gas comprises:
introducing at least one of hydrogen, ammonia, hydrides, or hydrocarbons.

9. The method of claim 7, wherein the introducing the reducing gas further comprises:
introducing an enhancing gas.

10. The method of claim 7, wherein the introducing the reducing gas further comprises:
combining the reducing gas with an inert gas.

11. The method of claim 1, wherein the illuminating comprises:
illuminating the ion implanted photoresist via a pulsed laser.

12. The method of claim 1, wherein the illuminating comprises:
illuminating the ion implanted photoresist with radiation having a wavelength in a range on the order of 150 to 550 nanometers (nm).

13. A method for removing ion implanted photoresist from a substrate, the method comprising:
introducing a first gas to a reaction chamber containing the substrate;
illuminating the ion implanted photoresist with radiation from a laser in the presence of the first gas;
scanning the radiation across the surface to remove an outer crust layer of the ion implanted photoresist;
replacing the first gas with a second gas in the reaction chamber; and
scanning the radiation across the surface in the presence of the second gas to remove a lower portion of the photoresist.

14. The method of claim 13, wherein the introducing the first gas comprises:
introducing a reducing gas.

15. The method of claim 14, wherein the introducing the reducing gas comprises:
introducing at least one of hydrogen, ammonia, hydrides, or hydrocarbons.

16. The method of claim 14, wherein the introducing the reducing gas further comprises:
combining the reducing gas with an enhancing gas.

17. The method of claim 14, wherein the introducing the reducing gas further comprises:
combining the reducing gas with an inert gas.

18. The method of claim 13, wherein the replacing comprises:
introducing an oxidizing gas.

19. The method of claim 18, wherein the introducing the oxidizing gas comprises:
introducing at least one of oxygen, ozone, hydrogen peroxide vapor, or a halogen.

20. The method of claim 18, wherein the introducing the oxidizing gas further comprises:
combining the oxidizing gas with an enhancing gas.

21. The method of claim 20, wherein the combining the oxidizing gas with the enhancing gas comprises:
using an enhancing gas comprising water vapor.

22. The method of claim 18, wherein the introducing the oxidizing gas further comprises;
combining the oxidizing gas with an inert gas.

23. The method of claim 13, wherein the illuminating comprises:
illuminating the ion implanted photoresist with a pulsed laser.

24. The method of claim 13, wherein the illuminating comprises:
illuminating the ion implanted photoresist with a laser wavelength in a range on the order of 150-550 nanometers (nm).

25. The method of claim 13, further comprising:
maintaining the substrate at an ambient temperature.

26. The method of claim 13, further comprising:
maintaining the substrate at a temperature in a range on the order of 120 degrees Celsius to minus 20 degrees Celsius.

27. The method of claim 13, wherein the introducing the first gas comprises:
maintaining a gas flow for the first gas in a range on the order of 0.5 to 50 standard liters per minute (SLM).

28. The method of claim 13, further comprising:
maintaining a chamber pressure in a range on the order of 1 to 760 Torr.

29. A method for removing ion implanted photoresist from a substrate, the ion implanted photoresist having an outer crust layer and an underlying portion, the underlying portion comprising unreacted photoresist, the method comprising:
introducing a first gas to a reaction chamber that contains the substrate;
scanning the radiation across the surface to remove the outer crust layer;
applying a coating to the underlying portion;
replacing the first gas with a second gas in the reaction chamber; and
scanning the radiation across the surface to remove the applied coating and the underlying portion.

30. The method of claim 29, wherein the applying comprises:
applying an anti-reflective coating.

31. The method of claim 30, wherein the applying the anti-reflective coating comprises:
applying an anti-reflective coating adapted to absorb a wavelength of the radiation.

32. A method for removing ion implanted photoresist from a substrate, the ion implanted photoresist having an outer crust layer and an underlying portion, the underlying portion comprising unreacted photoresist, the method comprising:
introducing a gas to a reaction chamber that contains the substrate;
scanning the radiation across the surface to remove the outer crust layer; and
removing the underlying photoresist by plasma ashing and wet bench cleaning, or with solvents.

33. The method of claim 32, wherein the introducing comprises:
introducing a reducing gas.

34. The method of claim 33, wherein the introducing the reducing gas comprises:
introducing at least one of hydrogen, ammonia, hydrides, or hydrocarbons.

35. The method of claim 33, wherein the introducing the reducing gas further comprises:
combining the reducing gas with an enhancing gas.

36. The method of claim 33, wherein the introducing the reducing gas further comprises:
combining the reducing gas with an inert gas.

37. The method of claim 32, further comprising:
maintaining a temperature of the substrate at ambient temperature.

38. The method of claim 32, further comprising:
maintaining a temperature of the substrate at a range on the order of minus 20 degrees centigrade to 120 degrees centigrade.

39. The method of claim 32, further comprising:
maintaining a chamber pressure in a range of approximately 1 Torr to 760 Torr.

40. The method of claim 32, wherein the introducing the gas comprises:
maintaining a gas flow in a range on the order of 0.5 to 50 standard liters per minute (SLM).

41. A method for removing ion implanted photoresist from a substrate, the method comprising:
directing a laser beam across a turning mirror;
expanding the laser beam with an optical expander to produce an expanded output beam;
reflecting the expanded output beam into a beam intensity flattener to produce an flattened output beam; and
reflecting the flattened output beam into an optical scan head that directs the flattened output beam through a window of a chamber containing the substrate and a gas; and
scanning the flattened output beam across the substrate to remove the ion implanted photoresist.
